(19) United States
(12) Patent Application Publication
(10) Pub. No.: US 2006/0103295 A1
(43) Pub. Date: May 18, 2006

(54) Non-pixellated display

(76) Inventors: Matthew Dewey Hubert, Columbia, SC (US); Andrew Woodthorpe, Santa Barbara, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 10/986,718

(22) Filed: Nov. 12, 2004

(51) Int. Cl. H05B 33/00

(52) U.S. Cl. 313/500; 313/505; 313/503; 430/313; 430/312; 445/24

(57) ABSTRACT

A non-pixellated segmented display is disclosed. The display comprises a first electrode having a first pattern, an insulator layer having a second pattern, an electroluminescent layer, and a second unpatterned electrode.

### FIELD OF THE INVENTION

This invention relates in general to electroluminescent displays. In particular, it relates to such displays which have at least one image which is not pixellated.

### BACKGROUND INFORMATION

Organic electronic devices are present in many different kinds of electronic equipment. In such devices, an active layer is sandwiched between two electrical contact layers. At least one of the electrical contact layers is light-transmitting so that light can pass through the electrical contact layer. One type of electronic device is an organic light emitting diode (OLED), which holds promise for display applications due to its high power conversion efficiency and low processing costs. OLED's typically contain an electroluminescent (EL) layer arranged between an anode and a cathode.

In many OLED applications, the display is pixellated to allow for changing information content. Pixellated displays are composed of a uniform array of small picture elements (“pixels”) which can be individually turned on or off to create different images. In passive matrix displays, the area of an individual pixel is defined by the intersection of individual column and row electrodes. Each pixel is addressed by applying an appropriate voltage bias to the column and row electrodes. In active matrix displays, individual pixel circuits are used to address each pixel.

These pixellated displays can require complex precision process techniques, which can be costly. For some displays, only simple, static images are required, and the complexity of pixellation is unnecessary. For example, the control panels for electronic devices frequently have icons which light up to indicate different sub-functions. The images remain the same, and are either on or off. These displays do not require pixellation. However, as electronic devices become smaller, the corresponding displays are also smaller. The displays, although not pixellated, do require high resolution. There is a continuing need for small, non-pixellated segmented displays and processes to make them.

### SUMMARY OF THE INVENTION

The invention relates to a non-pixellated electroluminescent display comprising,

a first electrode having a first pattern,

an insulator layer having a second pattern,

an electroluminescent layer, and

a second unpatterned electrode.

In another embodiment, the invention relates to a process for making a non-pixellated display having a viewing area and a non-viewing area, comprising
patterning a first electrode layer in the viewing area to form a first electrode pattern;
depositing an insulating layer;
patterning the insulating layer to form an insulating layer pattern;
depositing an organic electroluminescent material; and
depositing a second electrode overall.

In another embodiment, the invention relates to a process for making a non-pixellated display having a viewing area and a non-viewing area, comprising
depositing a first electrode on a substrate in at least the viewing area;
depositing an insulating layer;
patterning the insulating layer to form an insulating layer pattern;
depositing an organic electroluminescent material;
depositing a second electrode; and
patterning the second electrode to form a second electrode pattern, wherein depositing the second electrode and patterning the second electrode can be carried out simultaneously.

As used herein, the term “viewing area” refers to the area of a display which will be seen in an electronic device.

As used herein, the term “non-viewing area” refers to an area of a display which cannot be seen in an electronic device. The non-viewing area is generally on the same substrate as the viewing area, and may include electrical leads, bond pads, circuitry, etc.

As used herein, the term “non-pixellated,” as it refers to a display, is intended to mean that the display is not composed of a regular array of individual picture elements which can be individually addressed to form different images.

As used here, the term “segmented,” as it refers to a display, is intended to mean that the display has two or more static images.

As used herein, the term “static image” is intended to mean an image that is fixed and can be either on or off.

As used herein, the term “display thickness” refers to the sum of the thicknesses of the electrode layers and the layers therebetween.

As used herein, the term “extended display thickness” refers to the sum of the thicknesses of the substrate and cover layers and all the layers therebetween.

As used herein, the term “thickness” as it refers to a layer, is intended to mean the size of the dimension through the layer as opposed to its length or width in the plane parallel to the display.

As used herein, the term “width” as it refers to a pattern in a layer, is intended to mean the smallest dimension of the pattern in the plane parallel to the display.

As used herein, the terms “image” and “image element” refer to individual pictures which can be illuminated in a display. For example, an image element can be an icon on a control panel or a symbol indicating a function.

As used herein, the term “photolithographic technique” refers to a method for patterning a material, in which: the material is covered with a photosensitive layer; the photosensitive layer is imagewise exposed to activating radiation; the imagewise exposed layer is developed to remove either the exposed or unexposed areas; the material and remaining photosensitive layer are treated with wet or dry etchant to remove the areas of the material not covered by the remaining photosensitive layer.

Group numbers corresponding to columns within the periodic table of the elements use the “New Notation” convention as seen in the CRC Handbook of Chemistry and Physics, 81^{st} Edition (2000).

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

### BRIEF DESCRIPTION OF THE DRAWINGS

FIG. 1 is a cross-sectional view of a non-pixellated display of the invention.

FIG. 2 is a plan view of a substrate for a display, having a patterned first electrode thereon.

FIG. 3 is a plan view of the substrate in FIG. 2, further having metal traces thereon.

FIG. 4 is a plan view of a substrate for a display, having a patterned insulator layer over the patterned first electrode of FIG. 2.

### DETAILED DESCRIPTION

The electroluminescent display of the invention is non-pixellated and has one or more static images which can be illuminated. The display generally comprises two electrode layers, one of which is light-transmitting, with a layer of patterned insulating material and a layer of electroluminescent material between them. One of the electrode layers is patterned, and the other electrode is unpatterned, in at least the viewing areas. The display may also include a substrate, additional functional layers, and cover and/or sealing layers.

In the display of the invention, either the anode or the cathode can be patterned; either one or both of the anode and cathode can be light-transmitting; the display can be constructed such that either the anode or the cathode is closer to a substrate.

The patterned electrode has a pattern which electrically separates the image elements of the display. Thus, the pattern may be a simple grid, where each image element is contained within one of the grid units. The pattern may include terminal lines and lead lines. Thus, the electrode pattern may extend into the non-viewing area of the display. The pattern may also include one or more of the image elements. In one embodiment, the anode is patterned to form all the image elements and lead lines thereto. In one embodiment, the cathode is patterned to form contact pads corresponding to each one of the image elements.

The anode is an electrode that is more efficient for injecting holes compared to the cathode layer. The anode can include materials containing a metal, mixed metal, alloy, metal oxide or mixed-metal oxide. Suitable metals include the Group 11 metals, the metals in Groups 4, 5, and 6, and the Group 8-10 transition metals. If the anode layer is to be light transmitting, mixed-metal oxides of Groups 12, 13 and 14 metals, such as indium-tin-oxide, may be used. Some non-limiting, specific examples of materials for anode layer include indium-tin-oxide (“ITO”), aluminum-tin-oxide, gold, silver, copper, nickel, and selenium. The anode may also comprise an organic material such as polyaniline.

The cathode is an electrode that is particularly efficient for injecting electrons or negative charge carriers. The cathode layer can be any metal or nonmetal having a lower work function than the first electrical contact layer (in this case, the anode layer). Materials for the second electrical contact layer can be selected from alkali metals of Group 1 (e.g., Li, Na, K, Rb, Cs,), the Group 2 (alkaline earth) metals, the Group 12 metals, the rare earths, the lanthanides (e.g., Ce, Sm, Eu, or the like), and the actinides. Materials such as aluminum, indium, calcium, barium, yttrium, and magnesium, and combinations, may also be used. Specific non-limiting examples of materials for the cathode layer include barium, lithium, cerium, cesium, europium, rubidium, yttrium, magnesium, and samarium.

Each of the electrodes may be formed by a chemical or physical vapor deposition process or a liquid deposition process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as e-beam evaporation and resistance evaporation. Specific forms of physical vapor deposition include rf magnetron sputtering or inductively-coupled plasma physical vapor deposition (“IMP-PVD”). These deposition techniques are well known within the semiconductor fabrication arts.

The patterned electrode may be applied in the desired pattern. For examples, the electrode material can be vapor deposited through a patterned mask that is positioned over the substrate or underlying layer. Alternatively, the electrode material can be applied as an overall layer (also called blanket deposit) and subsequently patterned using, for example, a patterned resist layer and wet chemical or dry etching techniques. Other processes for patterning that are well known in the art can also be used.

The patterned insulating layer may be made of any electrically insulating material. In one embodiment, the insulating material is a photoresist. These materials are well known in the electronics arts, particularly in the manufacture of printed circuit boards. The photoresist can be in the form of a film or a liquid. The film can be applied to the electrode layer by pressing, lamination or other equivalent techniques. The liquid can be applied to the electrode layer by any known liquid deposition technique including, but not limited to continuous deposition techniques such as spin coating, gravure coating, curtain coating, dip coating, and slot-die coating; and discontinuous deposition techniques such as ink jet printing, gravure printing, screen printing, and thermal transfer methods.

The pattern is formed by imagewise exposing the photoresist to actinic radiation, for example, UV exposure through a mask or photographic negative. The exposure results in a difference in solubility, swellability or dispersibility between the exposed and unexposed areas of the resist. The photoresist is developed with a liquid developer to remove areas which are more soluble, swellable, or dispersible. For negative-working photoresists, the unexposed areas are removed with developer. For positive-working photoresists, the exposed areas are removed with developer. Exposure times and development conditions vary with the chemical composition of the resist, but are well known. Conventionally, when the resist is permanent, it is baked after development.

Other conventional insulating materials can also be used for the insulating layer. These include, but are not limited to, polymers, such as polyimides and fluoropolymers; metal oxides, such as silicon oxide; metal nitrides, such as silicon nitride; and combinations thereof. Such materials can be applied in a photosensitive composition and patterned as described above for the photoresist. Alternatively, the materials can be applied as an overall layer by liquid deposition, chemical deposition, or vapor deposition and subsequently patterned using conventional photolithographic techniques.

Any organic electroluminescent (“EL”) material can be used in the displays of the invention, including, but not limited to, fluorescent dyes, fluorescent and phosphorescent metal complexes, conjugated polymers, and mixtures thereof. Examples of fluorescent dyes include, but are not limited to, pyrene, perylene, rubrene, derivatives thereof, and mixtures thereof. Examples of metal complexes include, but are not limited to, metal chelated oxinoid compounds, such as tris(8-hydroxyquinolato)aluminum (Alq₃); cyclometalated iridium and platinum electroluminescent compounds, such as complexes of Iridium with phenylpyridine, phenylquinoline, or phenylpyrimidine ligands as disclosed in Petrov et al., Published PCT Application WO 02/02714, and organometallic complexes described in, for example, published applications US 2001/0019782, EP 1191612, WO 02/15645, and EP 1191614; and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The EL layer can be formed using any conventional means, including all the liquid deposition techniques discussed above. The layer can also be applied by thermal patterning, or chemical or physical vapor deposition.

The device may include a support or substrate that can be adjacent to the anode layer or the cathode layer. Frequently, the support is adjacent the anode layer. If the support is on the side of the display from which the images are to be viewed, then the support will be light-transmitting. The support can be flexible or rigid, organic or inorganic. Generally, glass or flexible organic films are used as a support. When the support is an organic film, it may include one or more additional layers to provide environmental protection, such as thin layers of metals, ceramics, or glasses.

The device may include a layer between the EL layer and the anode which facilitates hole injection and/or transport. Examples of materials which may facilitate hole-injection/transport comprise N,N′-diphenyl-N,N′-bis(3-methylphenyl)-[1,1′-biphenyl]4,4′-diamine (TPD) and bis[4-(N,N-diethylamino)-2-methylphenyl](4-methylphenyl)methane (MPMP); hole-transport polymers such as polyvinylcarbazole (PVK), (phenylmethyl)polysilane, poly(3,4-ethylenedioxythiophene) (PEDOT), and polyaniline (PANI), or the like; electron and hole-transporting materials such as 4,4′-N,N′-dicarbazole biphenyl (BCP); or light-emitting materials with good hole-transport properties such as chelated oxinoid compounds, including tris(8-hydroxyquinolato)aluminum (Alq₃) or the like.

The device may include a layer between the EL layer and the cathode which facilitates electron injection and/or transport. Examples of materials which may facilitate electron-injection/transport comprise metal-chelated oxinoid compounds (e.g., Alq₃ or the like); phenanthroline-based compounds (e.g., 2,9-dimethyl-4,7-diphenyl-1,10-phenanthroline (“DDPA”), 4,7-diphenyl-1,10-phenanthroline (“DPA”), or the like); azole compounds (e.g., 2-(4-biphenylyl)-5-(4-t-butylphenyl)-1,3,4-oxadiazole (“PBD” or the like), 3-(4-biphenylyl)-4-phenyl-5-(4-t-butylphenyl)-1,2,4-triazole (“TAZ” or the like); other similar compounds; or any one or more combinations thereof. Alternatively, this layer may be inorganic and comprise BaO, LiF, Li₂O, or the like.

The hole-injection/transport layer and the electron-injection/transport layer can be formed using any conventional means, including all the liquid deposition techniques discussed above. The layer can also be applied by thermal patterning, or chemical or physical vapor deposition.

The device may have a cover to provide physical and environmental protection. The cover may be made of any relatively impermeable material such as glass, ceramic, or metal. Alternatively, the cover may be made of polymers, such as parylenes or fluoropolymers, or of polymer composites with metal, glass or ceramic. The cover may be sealed to the support using conventional techniques, such as curable epoxy. In one embodiment, the cover has attached thereto a getter material which absorbs or adsorbs water and/or oxygen. In one embodiment, the getter is a molecular sieve. In a further embodiment, the getter in an inorganic binder is applied to a glass cover and heated to densify and activate. The heating step is carried out prior to attaching the cover to the display.

In other embodiments, additional layer(s) may be present within organic electronic devices. For example, a layer between the hole-injection/transport layer and the EL layer may facilitate positive charge transport, band-gap matching of the layers, function as a protective layer, or the like. Similarly, additional layers between the EL layer and the electron-injection/transport layer may facilitate negative charge transport, band-gap matching between the layers, function as a protective layer, or the like. Layers that are known in the art can be used. In addition, any of the above-described layers can be made of two or more layers. The choice of materials for each of the component layers may be determined by balancing the goals of providing a device with high device efficiency with the cost of manufacturing, manufacturing complexities, or potentially other factors.

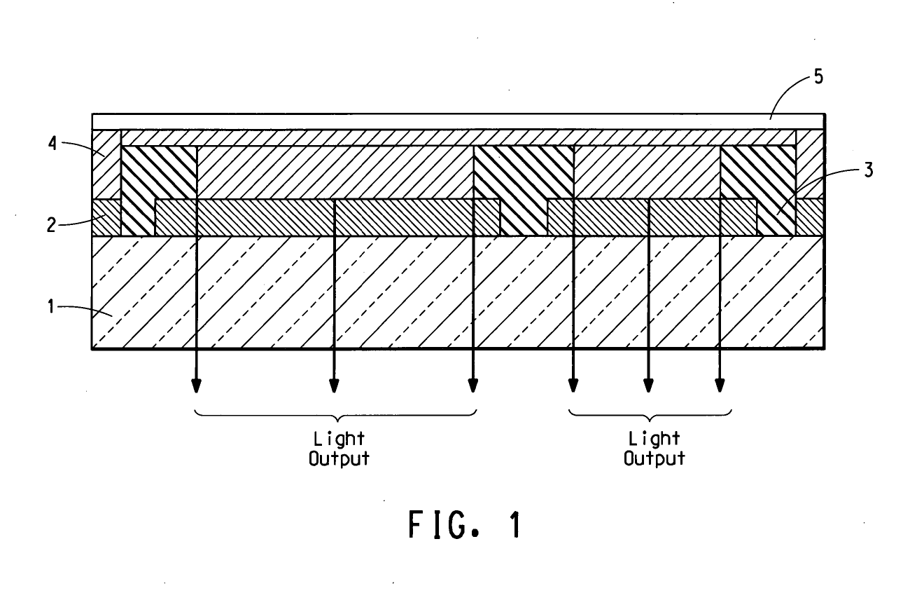

One embodiment of the display of the invention is illustrated in FIG. 1. A patterned anode 2 is on glass substrate 1. Over the anode is a patterned insulator layer 3. The organic EL layer 4 is over the insulator. The cathode layer 5 is an overall layer.

In one embodiment of the invention, the first step in the process for making the non-pixellated display comprises patterning a first electrode. In one embodiment the first electrode is on a substrate. In one embodiment the first electrode is a light-transmitting anode on a light-transmitting support. In one embodiment, the first electrode comprises indium tin oxide (“ITO”) on a glass support. ITO-coated glass substrates are commercially available. The ITO is patterned photolithographically to form a first electrode pattern. The first electrode pattern is in the viewing area of the display and may also be in the non-viewing area. In one embodiment, the first electrode pattern includes electrode terminals in the non-viewing area which are to be connected to the electrical leads. In one embodiment the first electrode pattern in the viewing area comprises the image elements with lead lines. The lead lines lead to the terminals in the non-viewing area.

Alternatively, the first electrode can be a cathode. The cathode may be patterned as described above for the anode.

Optionally, a conductive metal can be deposited to form trace lines and/or contact pads for the second electrode. The conductive metal is deposited in at least the non-viewing area and patterned photolithographically. The conductive metal is generally one having a high conductivity, such as chromium, aluminum, and the like.

The next step in the process is to deposit and pattern an insulating layer. The insulating layer pattern will have open areas in the image areas, so that there can be illumination in the image areas. The insulating layer pattern will also have open areas for any contact pads for the second electrode.

The next step in the process is to deposit the organic layers of the device. Typically, with polymeric light-emitting materials, the device will have a layer of hole transport material adjacent the anode and then a layer of light-emitting material. With small molecule light-emitting materials, the device will also have a layer of electron-transport adjacent the cathode. However, other layers may be present as described above. The methods of deposition are also discussed above. The organic layers are not patterned in the viewing area.

After deposition of the organic materials there may be organic material on the contact pads for the second electrode. The organic material is removed from the contact pads. This can be accomplished using any wet or dry etch technique, using a mask to protect the other areas of the display.

The next step in the process is to deposit the second electrode. The second electrode is deposited over the entire display.

To protect the display from physical and/or environmental damage, the display can be covered with a material which is relatively impermeable to oxygen and moisture. A cover of metal and/or polymer materials may be deposited directly onto the display after the second electrode, typically by chemical or physical deposition. Alternatively, the cover may be a preformed lid structure of metal, glass, or ceramic, which fits on the glass substrate over the display area. The lid is sealed to the glass outside the display area. Any known sealant can be used, such as an epoxy.

In another embodiment, the first step in the process for making the non-pixellated display comprises depositing a first electrode on a substrate, without any patterning in the viewing area. The first electrode may be patterned is the non-viewing area to form terminals and/or lead lines, but in the viewing area the first electrode is a continuous layer.

The optional conductive metal layer, the insulating layer, and the organic layers are then deposited and patterned as described above.

The next step in the process is to deposit the second electrode, followed by patterning the second electrode. The second electrode is patterned photolithographically to form a second electrode pattern. The second electrode pattern is in the viewing area of the display and may also be in the non-viewing area. In one embodiment, the second electrode pattern includes electrode terminals in the non-viewing area which are to be connected to the electrical leads. In one embodiment the second electrode pattern in the viewing area comprises the image elements with lead lines. The lead lines lead to the terminals in the non-viewing area.

An environmental cover may then be applied as described above.

Although described as single layers, each of the layers described above may be made of multiple layers having the same or different composition.

### EXAMPLES

### Example 1

This example illustrates the formation of a non-pixellated segmented electroluminescent display.

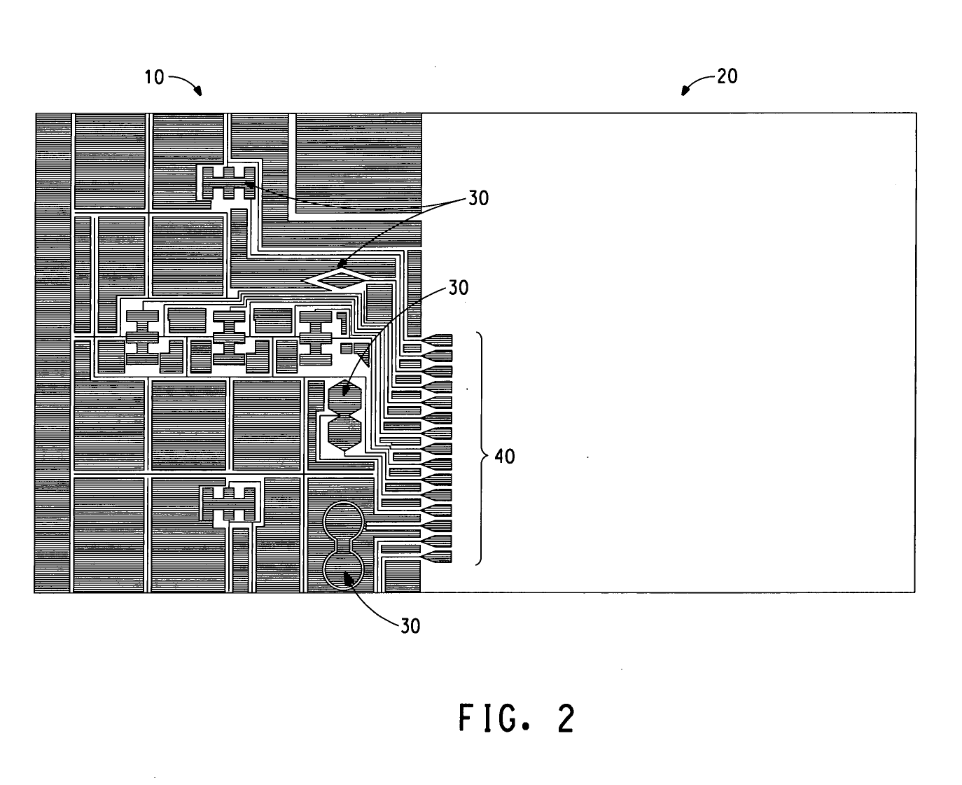

A 0.7 mm thick glass substrate coated with approximately 1500 Å indium tin oxide (ITO), was used to form the first electrode pattern. The total size was 11.03 mm by 11.23 mm, of which approximately 5.5 mm by 3.1 mm was intended to be the viewing area. The ITO layer was spin coated with a negative-working photoresist, imagewise exposed and developed to form a pattern on the ITO. This was then treated with etchant to remove the ITO in the areas not covered by the photoresist. The remaining photoresist was then stripped off. This resulted in the patterned first electrode illustrated in FIG. 2. The viewing area of the display is shown as 10, the non-viewing area as 20. The image areas 30 are isolated segments of ITO. The ITO pattern had terminals 40 at one edge, which were intended to be connected with the power supply.

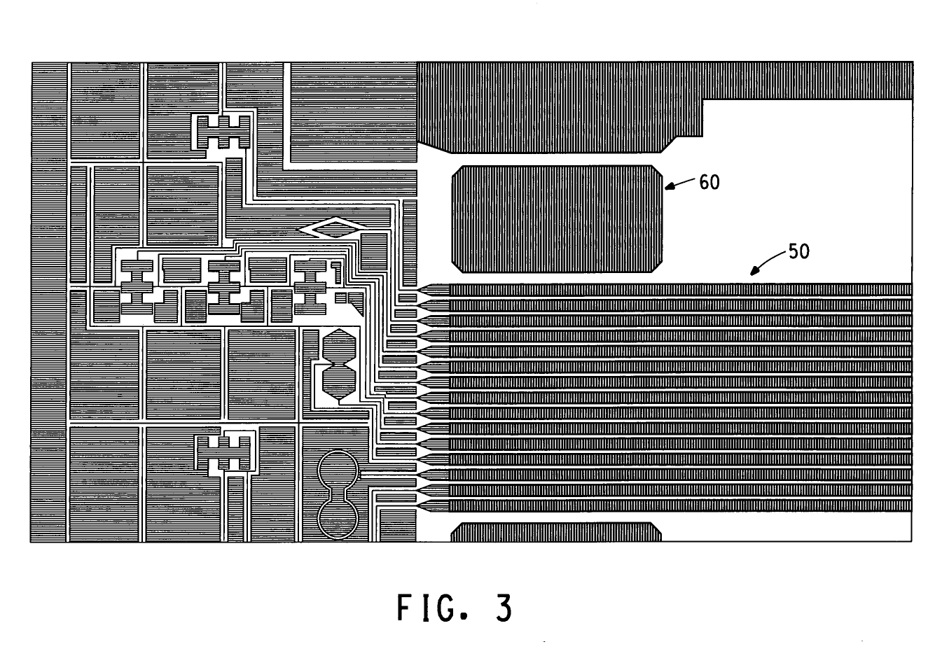

Conductive layers of Cr, Al, and Cr were then sputter deposited to a total thickness of about 3000 Å. A negative-working photoresist was applied, imagewise exposed and developed to form a pattern on the conductive metal. This was then treated with etchant to remove the conductive metal in the areas not covered by the photoresist, and the remaining photoresist was then stripped off. This resulted in metal traces 50 and cathode contact pad 60 in the non-viewing area as illustrated in FIG. 3.

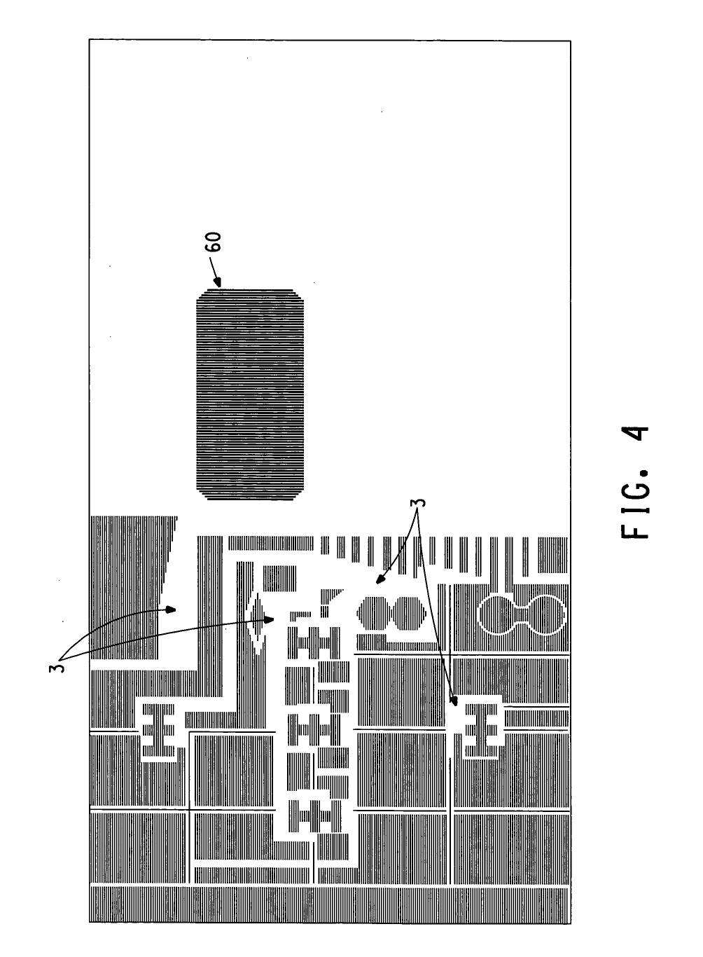

A negative-working photoresist was applied to a thickness of about 1.5 microns. The photoresist was imagewise exposed and developed to form a pattern of the insulating material 3 that was the negative of the ITO pattern in the image areas, and which completely covered the ITO terminals in the non-viewing area, as illustrated in FIG. 4. The Cr/Al/Cr traces 50 were also covered with the insulating material, while the cathode contact pad 60 was not covered. The remaining photoresist was then baked at 170° C. for 30 minutes.

The organic layers were then applied by spin coating. A buffer layer of poly(ethylenedioxythiophene)/PSSA (PEDOT/PSSA) was applied by spin-coating an aqeous solution of Baytron P (H. C. Starck GmbH, Germany) to which was added n-propyl alcohol and 1-methoxy-2-propanol, to a thickness of about 1700 Å. This was dried in air at 100° C. for 3 minutes. The buffer layer was then top-coated with a toluene solution of electroluminescent material, Super-yellow PDY 131 (Covion Company, Frankfurt, Germany), which is a poly(substituted-phenylene vinylene). The thickness of the electroluminescent (EL) layer was approximately 700 Å. Thicknesses of all films were measured with a TENCOR 500 Surface Profiler.

The organic materials were then removed from the cathode contact pad by laser ablation.

For the cathode, Ba and Al layers were vapor-deposited on top of the EL layer under a vacuum of 1×10⁻⁶ torr. The final thickness of the Ba layer was 20 Å; the thickness of the Al layer was 3500 Å.

To prepare a cover for the display, a slurry of 0.75 tablets of unfired DESIWAFER 300/20 zeolite material in 1 ml of water was dispersed in water to make a 200 ml dispersion. The dispersion was applied to a cavity on a glass lid plate in 0.5 ml aliquots by hand using a syringe. The zeolite material was solidified by placing in a vacuum oven for 1 hour at 70° C. to remove substantially all of the water. After solidification, the zeolite layers were then activated and densified by heating the glass lid plates for 2 hours at 500° C., to form a glass lid with self-attached getter. In an environment having less than 10 ppm H₂O and O₂, the plates with self-attached getter layers were then fitted over the display layers and attached to the glass substrate with UV-curable expoxy.

When a voltage of 3.5 was applied across the electrodes, the image areas were illuminated.

What is claimed is:

1. A non-pixellated electroluminescent display comprising,
a first electrode having a first pattern,
an insulator layer having a second pattern,
an electroluminescent layer, and
a second unpatterned electrode.

2. The display of claim 1, wherein at least a portion of the first pattern is the negative of the corresponding portion of the second pattern.

3. The display of claim 1, wherein the second pattern has multiple discrete areas.

4. The display of claim 1, wherein the second pattern has at least one segment having a width no greater than 20 microns.

5. The display of claim 1, wherein the display has a viewing area no greater than 18 mm by 18 mm.

6. The display of claim 1, wherein said display is segmented.

7. The display of claim 1, further comprising a substrate and a cover, said cover having a gettering material thereon.

8. The display of claim 1 having a display thickness no greater than 5 microns.

9. The display of claim 7 having an extended display thickness no greater than 2 mm.

10. A process for making a non-pixellated display having a viewing area and a non-viewing area, comprising
patterning a first electrode layer in the viewing area to form a first electrode pattern;
depositing an insulating layer;
patterning the insulating layer to form an insulating layer pattern;
depositing an organic electroluminescent material; and
depositing a second electrode overall.

11. A process for making a non-pixellated display having a viewing area and a non-viewing area, comprising
depositing a first electrode on a substrate in at least the viewing area;
depositing an insulating layer;
patterning the insulating layer to form an insulating layer pattern;
depositing an organic electroluminescent material;
depositing a second electrode; and
patterning the second electrode to form a second electrode pattern, wherein depositing the second electrode and patterning the second electrode can be carried out simultaneously.

12. The process of claim 10 or 11, further comprising
depositing a conductive metal in at least the non-viewing area;
patterning the conductive metal to form a conductive metal pattern.

13. The process of claim 10 or 11, further comprising
depositing a buffer layer between the organic electroluminescent material and the first electrode.

14. The process of claim 10 or 11, wherein the insulating material is a photoresist, and patterning of the photoresist is carried out by imagewise exposure and development.

15. The process of claim 14, further comprising baking after the development of the photoresist.

16. The process of claim 10 or 11, further comprising applying a cover having a gettering material thereon.

17. The process of claim 10 or 11, wherein the active area of the display is no greater than 18 mm by 18 mm.

18. The process of claim 10 or 11, wherein the display has a display thickness no greater than 5 microns.

19. The process of claim 10 or 11, wherein the display has an extended display thickness no greater than 2 mm.

20. A non-pixellated electroluminescent display, wherein the display has a viewing area no greater than 18 mm by 18 mm.

21. A non-pixellated electroluminescent display, wherein the display has a display thickness no greater than 5 microns.

22. A non-pixellated electroluminescent display, wherein the display has an extended display thickness no greater than 2 mm.

23. The display of claim 20, 21, or 22, wherein said display is segmented.
